(19) United States
(12) Patent Application Publication
(10) Pub. No.: US 2022/0380609 A1
(43) Pub. Date: Dec. 1, 2022

(54) Core-Shell Structured Composite Powder Electromagnetic Wave Absorber Formed by Coating Fe-Based Nanocrystalline Alloy with Carbon, and Preparation Method Thereof

(71) Applicant: Dalian University of Technology, Dalian (CN)

(72) Inventors: Yanhui Li, Dalian (CN); Wei Zhang, Dalian (CN); Changlu Shi, Dalian (CN)

(21) Appl. No.: 17/693,784

(22) Filed: Mar. 14, 2022

(30) Foreign Application Priority Data
May 28, 2021 (CN) 202110594303.0

(51) Int. Cl. C09D 5/32; C09D 1/00; H05K 9/00

(52) U.S. Cl. CPC C09D 5/32; C09D 1/00; H05K 9/0081

(57) ABSTRACT

Disclosed is a core-shell structured composite powder electromagnetic wave absorber formed by coating Fe-based nanocrystalline alloy with carbon and a preparation method thereof. The core-shell structured composite powder includes a core of an Fe-based nanocrystalline alloy, and a shell of an amorphous carbon layer, the shell accounting for 5-25 wt % of the core-shell structured composite powder electromagnetic wave absorber, wherein the core-shell structured composite powder electromagnetic wave absorber has a particle size of 3-10 μm; the Fe-based nanocrystalline alloy has a composition formula of Fe_{bal.}SiₐB_{b}, where atomic percentage contents of Si and B are 3-15 respectively, and a balance is the atomic percentage content of Fe.

### CROSS REFERENCE TO RELATED APPLICATION

This patent application is related to and claims priority benefits from Chinese Patent Application No. 202110594303.0, filed with the China National Intellectual Property Administration on May 28, 2021, entitled by “Core-Shell Structured Composite Powder Electromagnetic Wave Absorber Formed By Coating Fe-Based Nanocrystalline Alloy With Carbon”. The '303.0 application is incorporated by reference herein in its entirety as part of the present disclosure.

### FIELD OF THE INVENTION

The present disclosure relates to the technical field of new materials, in particular, to a core-shell structured composite powder electromagnetic wave absorber formed by coating Fe-based nanocrystalline alloy with carbon, and a preparation method thereof.

As electronic equipment has been developing in the direction of miniaturization, integration and high-frequency, coupled with the popularization of new generation wireless communication, wireless charging and other technologies and the advancement of radar detection technology, high-frequency electromagnetic waves with frequencies in an order of GHz have been using in civilian and military fields more commonly. The resulting electromagnetic radiation and interference have become a new source of pollution following water pollution, air pollution and noise pollution. Electromagnetic wave radiation and interference not only cause great interference to electronic equipment, precision instruments, communication signals, etc., but also adversely affect human health. It is of great significance and value to develop high-performance electromagnetic wave shielding materials or electromagnetic wave absorbing materials to overcome the harm caused by electromagnetic wave radiation and interference.

Fe-based nanocrystalline soft magnetic alloys have broad application prospects in the field of GHz-band electromagnetic wave absorption due to their high saturation magnetization and high-frequency permeability. However, their mono-magnetic loss, high density, and prone to corrosion make them difficult to meet comprehensive requirements of modern high-performance absorbing materials. Carbon materials such as graphite with good dielectric loss characteristics have advantages of low density, high thermal stability and corrosion resistance, but a mono-carbon material also has the shortcomings of narrow electromagnetic wave absorbing frequency range and low absorbing ability. The composite modification of Fe-based nanocrystalline alloys and carbon materials is expected to achieve the synergistic effect of magnetic loss-dielectric loss, and improve the wave absorbing performance while reducing the density and enhancing the stability of the wave absorber.

Carbon materials and magnetic alloys are generally composited in the form of a simple blending, laminates, shell-core structures or capsules. CHUAI et al., Enhanced Microwave Absorption Properties of Flake-Shaped FePCB Metallic Glass/Graphene Composites, Composites Part A: Applied Science and Manufacturing, Vol. 89 (October 2016) pages 33-39, “CHUAI”, discusses first preparing Fe_{0.2}P_{0.05}C_{0.45}B_{0.3} amorphous powder by gas atomization method, and then mixing the amorphous powder and graphene by ball milling, obtaining a composite powder. The wave absorbing coating prepared from the composite powder with a thickness of 2.0 mm exhibits a minimal reflection loss (RLₘᵢₙ) of −45.3 dB, but an effective absorption bandwidth (Δf_{RL<-10 dB}), i.e. the frequency range where the reflection loss (RL) was lower than −10 dB, of only 5.4 GHz. It is difficult to realize surface modification of the alloy by a simple blending, and agglomeration would occur during the blending of powder. JUN, The Study on The Surface Modification for Iron Based Magnetic Power Absorption Agent, Master's Thesis of Huazhong University of Science and Technology (2012) discuses blending the Fe-based magnetic powder with TiO₂, and found that the wave absorbing performance was not significantly improved, and that the obvious agglomeration of the TiO₂ occurred. The core-shell structured composite absorber with a magnetic alloy as the core and a carbon material as the shell could allow for not only the complementary of magnetic/dielectric loss, but also the interface polarization effect at the heterogeneous interface between the core and the shell, and thereby offer improved absorbing performance, and also enhanced corrosion resistance and oxidation resistance. In addition, the wave absorbing performance could also be adjusted by changing the ratio of the core to the shell, morphology, and spatial position. At present, the core-shell electromagnetic wave absorbers are commonly prepared by hydrothermal/solvothermal, electroless plating/electroplating, arc discharge plasma, and sol-gel methods. LV et al., Coin-like α-Fe2O3@CoFe2O4 Core-Shell Composites with Excellent Electromagnetic Absorption Performance, ACS Appl Mater Inter, Vol. 8 (February 2015) pages 4744-4750, “LV”, synthesized a Fe₂O₃@CoFe₂O₄ composite by a hydrothermal reaction method, and achieved a RLₘᵢₙ of −60 dB at a frequency of 16.5 GHz and a Δf_{RL<-10 dB} of 5 GHz when the coating thickness is 2 mm. KUANG et al., Facile Synthesis and Influences of Fe/Ni Ratio on the Microwave Absorption Performance of Ultra-Small Feni-C Core-Shell Nanoparticles, Mater Res Bull 126 (2020) 110837, “KUANG”, prepared ultrafine FeNi-C core-shell nanoparticles by using a chemical vapor deposition method. When the coating thickness is 2.2 mm, the RLₘᵢₙ is −63.7 dB and the Δf_{RL<-10 dB} is 6.5 GHz. ZHANG et al., Microwave Absorption Properties of the Carbon-Coated Nickel Nanocapsules, Appl Phys Lett, Vol. 89 (2006) 053115), “ZHANG”, synthesized Ni@C nanoparticles by using an arc plasma method, and achieved an RLₘᵢₙ of −32 dB at a frequency of 13 GHz and a Δf_{RL<-10 dB} of 4.3 GHz. Although the above-mentioned core-shell structured electromagnetic wave absorbers exhibit good wave absorbing properties, their preparations are mostly limited to the laboratory, which are complicated and offer low efficiency for production. Thus, it is difficult for them to be applied to large-scale industrial production. Therefore, it is of great significance to invent an electromagnetic wave absorber which exhibits excellent comprehensive wave absorbing properties and has a simple and efficient preparation process.

### SUMMARY OF THE INVENTION

In view of the shortcomings of current electromagnetic wave absorbers in terms of comprehensive wave absorbing performance or preparation process requirements, the present disclosure provides a core-shell structured composite powder electromagnetic wave absorber formed by coating Fe-based nanocrystalline alloy with carbon and a preparation method thereof, which has advantages of excellent comprehensive wave absorbing performance and simple and efficient preparation process.

The present disclosure provides the following technical solutions:

Disclosed is a core-shell structured composite powder electromagnetic wave absorber formed by coating Fe-based nanocrystalline alloy with carbon, which comprises a core of an Fe-based nanocrystalline alloy, and a shell of an amorphous carbon layer, the shell accounting for 5-25 wt % of the core-shell structured composite powder electromagnetic wave absorber, wherein

the core-shell structured composite powder electromagnetic wave absorber has a spherical-like core-shell structure, and a particle size of 3-10 μm;

the Fe-based nanocrystalline alloy has a composition formula of Fe_{bal.}SiₐB_{b}, where a and b represent an atomic percentage content of a corresponding element respectively, and meet requirements of

3≤a≤15,

3≤b≤15, and

a balance being an atomic percentage content of Fe;

the Fe-based nanocrystalline alloy has an amorphous/α-Fe dual-phase structure, wherein the α-Fe has a grain size of 10-30 nm; and

the amorphous carbon layer has an average thickness of 0.3-1 μm.

In some embodiments, the Fe-based nanocrystalline alloy has a composition formula of Fe_{bal.}CoₓNi_{y}SiₐB_{b}C_{c}Cu_{d}TMₑ,

where TM represents at least one selected from the group consisting of Nb, Mo, Cr, and Mn; x, y, a, b, c, d, and e represent an atomic percentage content of a corresponding element respectively, and meet requirements of

0≤x≤15,

0≤y≤15,

0≤x+y≤20,

0≤a≤15,

0≤b≤15,

0≤c≤15,

6≤a+b+c≤30,

0≤d≤2,

0≤e≤4, and

a balance being an atomic percentage content of Fe.

In some embodiments, an electromagnetic wave absorber coating is formed from a mixture of the above-mentioned core-shell structured composite powder electromagnetic wave absorber and a wave-transparent matrix in a mass ratio of 3:2, and under a condition that the electromagnetic wave absorber coating has a thickness of 1.5-2.5 mm, the electromagnetic wave absorber coating exhibits a Δf_{RL<-10 dB} of 8-18 GHz, and a RLₘᵢₙ of −54 dB.

The present disclosure also provides a method for preparing the above-mentioned core-shell structured composite powder electromagnetic wave absorber formed by coating Fe-based nanocrystalline alloy with carbon, comprising

step 1, preparing a Fe-based nanocrystalline alloy powder by

a. providing raw materials according to a nominal composition formula of the Fe-based nanocrystalline alloy, each of the raw materials having a purity of not less than 99 wt %;

b. mixing the raw materials, and melting a resulting mixed material in an induction melting furnace or a non-consumable-electrode arc furnace in an argon atmosphere, to obtain a chemically uniform master alloy ingot;

c. crushing the master alloy ingot and screening, to obtain an alloy powder with a particle size of less than 300 μm; and

d. placing the alloy powder in a stainless steel ball mill tank in a ball-to-powder mass ratio of 20:1; vacuumizing the stainless steel ball mill tank and charging with argon gas, sealing the stainless steel ball mill tank and placing the sealed stainless steel ball mill tank in a planetary ball mill, and ball milling for 50-85 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the Fe-based nanocrystalline alloy powder with a particle size of 2-8 μm;

step 2, using a commercial carbon powder or preparing a carbon powder by steps of

a. mechanically crushing graphite and screening, to obtain a graphite powder with a particle size of less than 300 μm; and

b. placing the graphite powder in a stainless steel ball mill tank in a ball-to-powder mass ratio of 20:1, vacuumizing the stainless steel ball mill tank and charging with argon gas, sealing the stainless steel ball mill tank and placing the sealed stainless steel ball mill tank in a planetary ball mill, and ball milling for 30 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the carbon powder with a particle size of 1-3 μm; and

step 3, preparing a core-shell structured composite powder electromagnetic wave absorber by

mixing the Fe-based nanocrystalline alloy powder obtained in step 1 and the carbon powder obtained in step 2 in a preset ratio, and placing a resulting mixture in a stainless steel ball milling tank in a ball-to-powder mass ratio of 20:1 or 30:1, vacuumizing the stainless steel ball mill tank and charging with argon gas, sealing the stainless steel ball mill tank and placing the sealed stainless steel ball mill tank in a planetary ball mill, and ball milling for 6-10 h, at a rotation speed of 200 rpm, with a shut down of 5 minutes for every 30 minutes of milling to cool, in a forward and reverse operation mode to ensure a uniform ball milling; cooling for 0.5 h and taking out, to obtain the core-shell structured composite powder electromagnetic wave absorber with a particle size of 3-10 μm.

Compared with the prior art, technical solutions according to the present disclosure have the following advantages:

1. The composite powder electromagnetic wave absorber formed by coating Fe-based nanocrystalline alloy with carbon according to the present disclosure, having a spherical-like core-shell structure, allows for significantly improved impedance matching of the composite powder, and a synergistic effect of magnetic-dielectric loss, and exhibits significantly better wave absorbing performance than a mono-magnetic-loss type or a mono-dielectric-loss type wave absorber. Particularly, the composite powder electromagnetic wave absorber exhibits excellent comprehensive wave absorbing performance within a frequency of 8-18 GHz, such as thin absorbing layer, great wave absorbing ability, and wide effective absorbing frequency band.

2. The composite powder electromagnetic wave absorber formed by coating Fe-based nanocrystalline alloy with carbon comprises carbon on the external surface, which eliminates the drawbacks of easy corrosion of metal powder, and also reduces the overall density of the composite powder, thereby making the wave absorber lighter.

3. The method for preparing the composite powder electromagnetic wave absorber formed by coating Fe-based nanocrystalline alloy with carbon according to the present disclosure has simple preparation process, high production efficiency, and could be applied to mass production in industry. The morphology and particle size of the composite powder and the microstructure of the core nanocrystalline alloy could also be controlled by changing the ball milling process, thereby regulating the electromagnetic wave absorbing performance of the composite powder.

In summary, the core-shell structured composite powder electromagnetic wave absorber formed by coating Fe-based nanocrystalline alloy with carbon according to the present disclosure exhibits excellent comprehensive electromagnetic wave absorbing performance and has advantages of simple preparation process, which solves the problems of poor performance of the existing electromagnetic wave absorbers with mono-loss mechanism and/or their complicated preparation process.

### BRIEF DESCRIPTION OF THE DRAWINGS

FIG. 1 shows the X-ray diffraction (XRD) pattern of the composite powder as prepared in Example 1.

FIG. 2 is a scanning electron microscope (SEM) image of the composite powder as prepared in Example 1.

FIG. 3 is a graph showing a hysteresis loop of the composite powder as prepared in Example 1.

FIG. 4 is a graph showing the variation of the complex permeability and complex permittivity of the composite powder/paraffin coating as prepared in Example 1 with a thickness of 2 mm within a frequency range of 2-18 GHz.

FIG. 5 is a graph showing the variation of the RL of the composite powder/paraffin coating as prepared in Example 1 with different thicknesses within a frequency range of 2-18 GHz.

FIG. 6A is a transmission electron microscopy (TEM) image of the composite powder as prepared in Example 1.

FIG. 6B is a higher resolution transmission electron microscopy (TEM) image of the composite powder as prepared in Example 1.

FIG. 6C is a corresponding selected area electron diffraction (SAED) pattern of FIG. 6A.

### DETAILED DESCRIPTION OF ILLUSTRATIVE EMBODIMENT(S)

In order to explain the embodiments of the present disclosure or the technical solutions in the prior art more clearly, drawings that are needed in the descriptions of embodiments or the prior art are briefly described below. Obviously, the drawings described below are some embodiments of the present disclosure. For those of ordinary skill in the art, other drawings could be obtained on the basis of these drawings without creative labor.

It should be noted that the embodiments of the present disclosure and the features in the embodiments could be combined with each other if there is no conflict. Hereinafter, the technical solutions of the present disclosure will be described in detail in conjunction with the drawings and the examples.

To make the object, technical solutions, and advantages of the embodiments of the present disclosure clearer, the technical solutions in the embodiments of the present disclosure will be described clearly and completely in conjunction with the accompanying drawings in the embodiments of the present disclosure. Obviously, the described examples are only part of the examples of the present disclosure, rather than all the examples. The following description of at least one exemplary example is actually only illustrative, and in no way serves as any limitation to the present disclosure and its application or use. On the basis of the examples of the present disclosure, all other examples obtained by those of ordinary skill in the art without creative work shall fall within the scope of the present disclosure.

The following non-limiting examples may enable those of ordinary skill in the art to more fully understand technical solutions of the present disclosure, but do not limit the present disclosure in any way.

Unless otherwise specified, the test methods described in the following examples were conventional methods. Unless otherwise specified, the reagents and materials were commercially available.

The term “optimum matching thickness (dm)” used therein refers to a thickness of which the composite powder/paraffin composite coating sample could exhibit the lowest RL among the thicknesses.

The term “optimum matching frequency (fm)” used therein refers to a frequency at which the composite powder/paraffin composite coating sample could exhibit the lowest RL.

The present disclosure provides a core-shell structured composite powder electromagnetic wave absorber formed by coating Fe-based nanocrystalline alloy with carbon, which comprises a core of an Fe-based nanocrystalline alloy, and a shell of an amorphous carbon layer, the shell accounting for 5-25 wt % of the core-shell structured composite powder electromagnetic wave absorber, wherein

the core-shell structured composite powder electromagnetic wave absorber has a spherical-like core-shell structure, and a particle size of 3-10 μm;

the Fe-based nanocrystalline alloy has a composition formula of Fe_{bal.}SiₐB_{b}, where a and b represent an atomic percentage content of a corresponding element respectively, and meet requirements of

3≤a≤15,

3≤b≤15, and

a balance being an atomic percentage content of Fe;

the Fe-based nanocrystalline alloy has an amorphous/α-Fe dual-phase structure, wherein the α-Fe has a grain size of 10-30 nm; and

the amorphous carbon layer has an average thickness of 0.3-1 μm.

In some embodiments, the Fe-based nanocrystalline alloy has a composition formula of Fe_{bal.}CoₓNi_{y}SiₐB_{b}C_{c}Cu_{d}TMₑ,

where TM represents at least one selected from the group consisting of Nb, Mo, Cr, and Mn; x, y, a, b, c, d, and e represent an atomic percentage content of a corresponding element respectively, and meet requirements of

0≤x≤15,

0≤y≤15,

0≤x+y≤20,

0≤a≤15,

0≤b≤15,

0≤c≤15,

6≤a+b+c≤30,

0≤d≤2,

0≤e≤4, and

a balance being an atomic percentage content of Fe.

In some embodiments, an electromagnetic wave absorber coating is formed from a mixture of the above-mentioned core-shell structured composite powder electromagnetic wave absorber and a wave-transparent matrix in a mass ratio of 3:2, and under a condition that the electromagnetic wave absorber coating has a thickness of 1.5-2.5 mm, the electromagnetic wave absorber coating exhibits a Δf_{RL<-10 dB} of 8-18 GHz, and a minimum reflection loss of −54 dB.

The present disclosure also provides a method for preparing the above-mentioned core-shell structured composite powder electromagnetic wave absorber formed by coating Fe-based nanocrystalline alloy with carbon, comprising

step 1, preparing a Fe-based nanocrystalline alloy powder by

a. providing raw materials according to a nominal composition formula of the Fe-based nanocrystalline alloy, each of the raw materials having a purity of not less than 99 wt %;

b. mixing the raw materials, and melting a resulting mixed material in an induction melting furnace or a non-consumable-electrode arc furnace in an argon atmosphere, to obtain a chemically uniform master alloy ingot;

c. crushing the master alloy ingot and screening, to obtain an alloy powder with a particle size of less than 300 μm; and

d. placing the alloy powder in a stainless steel ball mill tank in a ball-to-powder mass ratio of 20:1; vacuumizing the stainless steel ball mill tank and charging with argon gas, sealing the stainless steel ball mill tank and placing the sealed stainless steel ball mill tank in a planetary ball mill, and ball milling for 50-85 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the Fe-based nanocrystalline alloy powder with a particle size of 2-8 μm;

step 2, using a commercial carbon powder or preparing a carbon powder by steps of

a. mechanically crushing graphite and screening, to obtain a graphite powder with a particle size of less than 300 μm; and

b. placing the graphite powder in a stainless steel ball mill tank in a ball-to-powder mass ratio of 20:1, vacuumizing the stainless steel ball mill tank and charging with argon gas, sealing the stainless steel ball mill tank and placing the sealed stainless steel ball mill tank in a planetary ball mill, and ball milling for 30 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the carbon powder with a particle size of 1-3 μm; and

step 3, preparing a core-shell structured composite powder electromagnetic wave absorber by

mixing the Fe-based nanocrystalline alloy powder obtained in step 1 and the carbon powder obtained in step 2 in a preset ratio, and placing a resulting mixture in a stainless steel ball milling tank in a ball-to-powder mass ratio of 20:1 or 30:1, vacuumizing the stainless steel ball mill tank and charging with argon gas, sealing the stainless steel ball mill tank and placing the sealed stainless steel ball mill tank in a planetary ball mill, and ball milling for 6-10 h, at a rotation speed of 200 rpm, with a shut down of 5 minutes for every 30 minutes of milling to cool, in a forward and reverse operation mode to ensure a uniform ball milling; cooling for 0.5 h and taking out, to obtain the core-shell structured composite powder electromagnetic wave absorber with a particle size of 3-10 μm.

### EXAMPLE 1

### Fe-Based Nanocrystalline Alloy of Fe₉₀Si₇B₃ as the Core of the Composite Powder

The method for preparing the core-shell structured composite powder electromagnetic wave absorber formed by coating Fe-based nanocrystalline alloy with carbon was as follows:

Step 1, Preparing a Fe-Based Nanocrystalline Alloy Powder

a. raw materials of Fe, Si, and B (each with a purity of not less than 99 wt %) were weighed according to the nominal composition of Fe₉₀Si₇B₃, and mixed;

b. the resulting mixed material was smelted repeatedly for four times in a non-consumable-electrode arc furnace in an argon atmosphere, obtaining a chemically uniform master alloy ingot;

c. the master alloy ingot was mechanically crushed and screened, obtaining an alloy powder with a particle size of less than 300 μm; and

d. the alloy powder was placed in a stainless steel ball milling tank in a ball-to-powder mass ratio of 20:1. The stainless steel ball milling tank was then vacuumized, charged with argon gas as a protective gas, and sealed. The sealed stainless steel ball milling tank was placed in a planetary ball mill for ball milling. The ball milling was performed for 85 h, at a rotation speed of 350 rpm, with a shut down of 5 minutes for every 30 minutes of milling to cool, in a forward and reverse operation mode to ensure a uniform ball milling. After a cooling of 0.5 h, a product was taken out, obtaining the Fe-based nanocrystalline alloy powder with a particle size of 2.8 μm.

Step 2, Preparing a Carbon Powder

a. the commercial graphite was mechanically crushed and screened, obtaining a graphite powder with a particle size of less than 300 μm; and

b. the graphite powder was placed in a stainless steel ball milling tank in a ball-to-powder mass ratio of 20:1. The stainless steel ball milling tank was then vacuumized, charged with argon gas as a protective gas, and sealed. The sealed stainless steel ball milling tank was placed in a planetary ball mill for ball milling. The ball milling was performed for 30 h, at a rotation speed of 350 rpm, with a shut down of 5 minutes for every 30 minutes of milling to cool, in a forward and reverse operation mode to ensure a uniform ball milling. After a cooling of 0.5 h, a product was taken out, obtaining the carbon powder with a particle size of 1-3 μm.

Step 3, Preparing a Composite Powder Formed by Coating Fe-Based Nanocrystalline Alloy with Carbon

the Fe-based nanocrystalline alloy powder obtained in step 1 and the carbon powder obtained in step 2 were mixed in a weight ratio of 92:8, and placed in a stainless steel ball milling tank in a ball-to-powder mass ratio of 20:1. The stainless steel ball milling tank was vacuumized, charged with argon gas as a protection gas, and sealed. The sealed stainless steel ball milling tank was placed in a planetary ball mill for ball milling. The balling milling was performed for 10 h, at a rotation speed of 200 rpm, with a shut down of 5 minutes for every 30 minutes of milling to cool, in a forward and reverse operation mode to ensure a uniform ball milling. After a cooling of 0.5 h, a product was taken out, obtaining the composite powder with a particle size of 3-10 μm.

Step 4, Structure Characterization, Morphology Observation and Performance Test of the Composite Powder

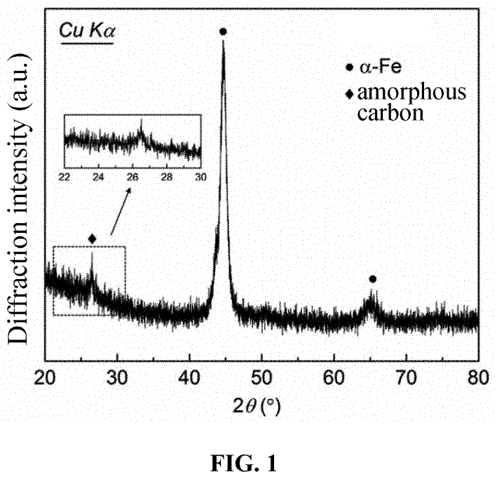

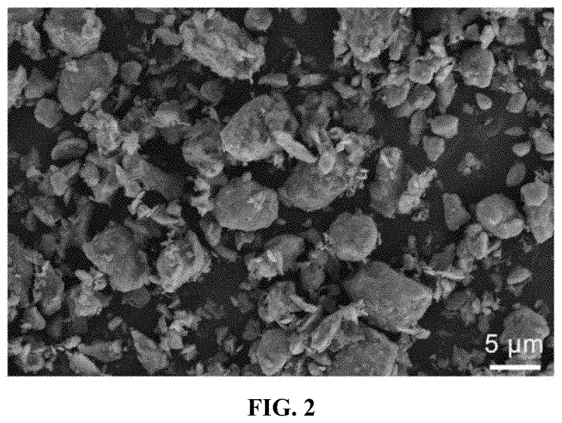

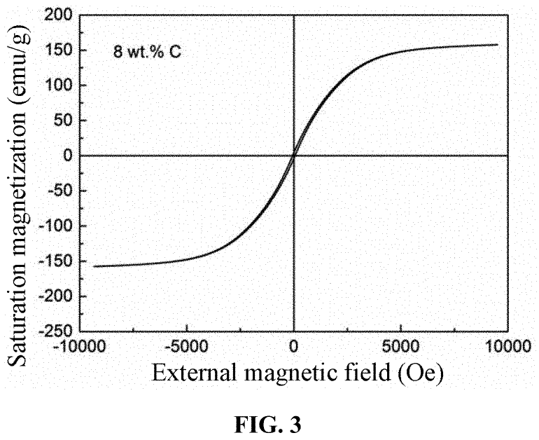

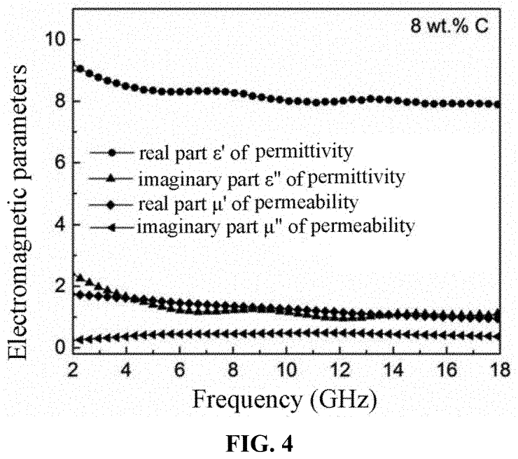

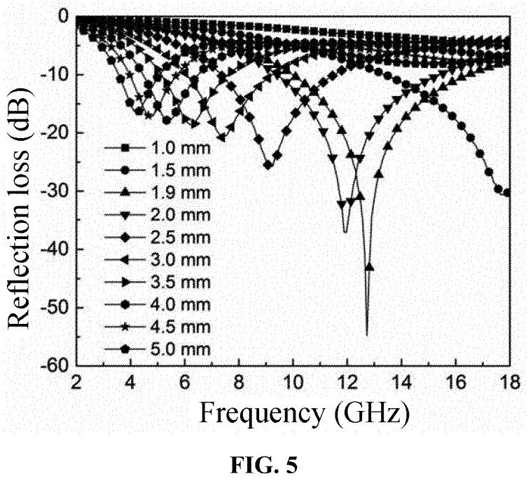

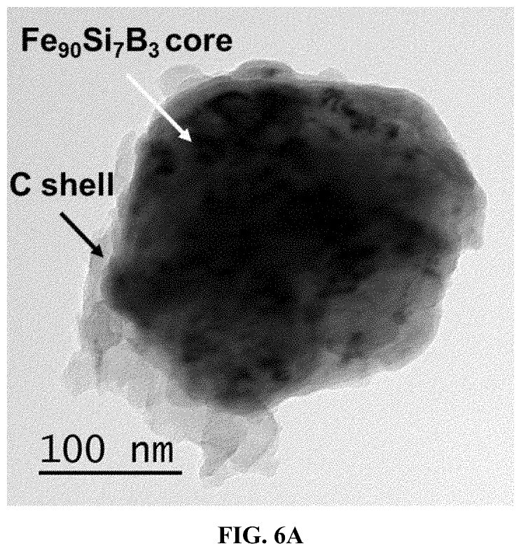

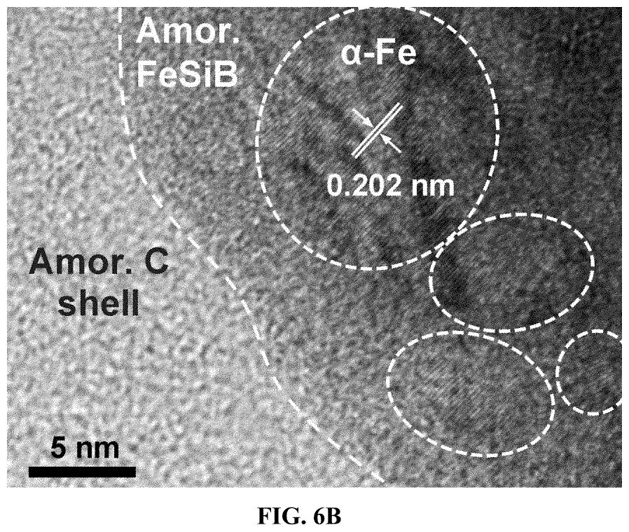

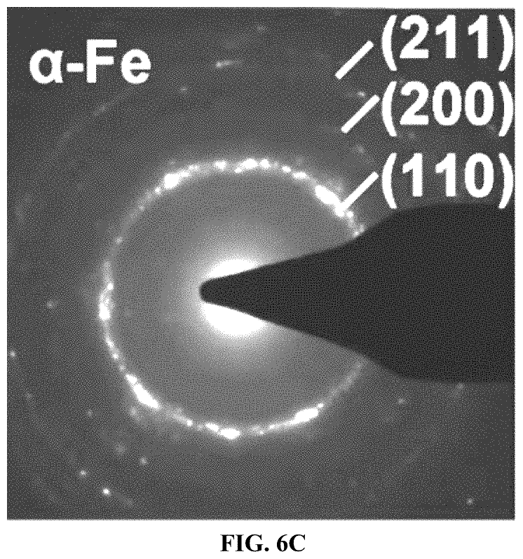

Microstructure of the composite powder was characterized by XRD. As shown in FIG. 1 and FIGS. 6A-6C, the composite powder has a multiphase microstructure including nanocrystalline α-Fe/amorphous alloy core and amorphous carbon shell, and the Fe-based nanocrystalline alloy has an average grain size of about 7 nm. The morphology of the composite powder was observed by SEM. As shown in FIG. 2, the composite powder has an irregular spherical morphology, and has an average particle size of 3.4 μm. The magnetic properties of the composite powder were measured by a vibrating sample magnetometer (VSM). FIG. 3 shows the magnetic properties of the composite powder. The composite powder exhibits typical soft magnetic properties, and a saturation magnetization (Ms) of 157.6 emu/g. The composite powder and paraffin were mixed to be uniform in a weight ratio of 3:2, and then pressed into a ring composite coating sample with an outer diameter of 7 mm, an inner diameter of 3 mm, and a thickness of 2 mm. The complex permeability μ=μ′−jμ″ and complex permittivity ε=ε′−jε″ of the ring composite coating sample within a frequency of 2-18 GHz were measured by using vector network analyzer. As shown in FIG. 4, the permittivity of the composite coating sample prepared from the composite powder increases significantly. The RL curve of the composite coating sample prepared from the composite powder electromagnetic wave absorber was calculated according to the transmission line principle in combination with measured electromagnetic parameters, to evaluate electromagnetic wave absorbing performance of the composite coating sample. The simulated curve of RL with different thicknesses as a function of frequency is shown in FIG. 5. As shown in FIG. 5, the composite powder/paraffin composite coating sample with an optimum matching thickness (dₘ) of 1.9 mm exhibits great electromagnetic wave absorbing ability within a frequency of 10.0-16.5 GHz, a RLₘᵢₙ of −54.8 dB at an optimum matching frequency (fₘ) of 12.7 GHz, and Δf_{RL<-10 dB} of 6.5 GHz. In addition, when the thickness was 1.7 mm, the Δf_{RL<-10 dB} is 7.3 GHz, covering most of the X-band (8-12 GHz) and the entire Ku-band (12-18 GHz).

### EXAMPLE 2

### Fe-Based Nanocrystalline Alloy of Fe₉₀Si₇B₃ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that in step 3, the Fe-based nanocrystalline alloy powder and the carbon powder were mixed in a weight ratio of 85:15.

The composite powder had a spherical-like morphology, and an average particle size of 3.7 μm. The composite powder had a multiphase microstructure including nanocrystalline α-Fe/amorphous alloy core and amorphous carbon shell, and exhibits a Mₛ of 145.7 emu/g, with a typical soft magnetic properties. The composite powder/paraffin composite coating sample with an optimum matching thickness of 1.6 mm exhibited a RLₘᵢₙ of −23.2 dB at a frequency of 17.5 GHz, and a Δf_{RL<-10 dB} of 4.2 GHz.

### EXAMPLE 3

### Fe-Based Nanocrystalline Alloy of Fe₈₇Si₃B₁₀ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₈₁Si₃B₁₀, and the ball milling was performed for 70 h; in step 3, the Fe-based nanocrystalline alloy powder and the carbon powder were mixed in a weight ratio of 95:5. The Fe-based nanocrystalline alloy powder had an average particle size of 7.4 μm

The composite powder had a multiphase microstructure including nanocrystalline α-Fe/amorphous alloy core and amorphous carbon shell. The composite powder had a spherical-like morphology, and an average particle size of 8 μm. The composite powder exhibited typical soft magnetic properties, and a Mₛ of 163.4 emu/g. The permittivity of the composite powder/paraffin composite coating sample increased, and the permeability decreased slightly. The composite coating sample with an optimum matching thickness of 2.3 mm exhibited a RLₘᵢₙ of −17.5 dB, and a Δf_{RL<-10 dB} of 5.1 GHz.

### EXAMPLE 4

### Fe-Based Nanocrystalline Alloy of Fe₈₂Si₁₅B₃ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₈₂Si₁₅B₃, and the ball milling was performed for 50 h; in step 3, the Fe-based nanocrystalline alloy powder and the carbon powder were mixed in a weight ratio of 75:25, and the ball-to-powder mass ratio was adjusted to 30:1. The alloy particles (as the core) had an average particle size of 8 μm.

The composite powder had an irregular spherical morphology, and an average particle size of 10 μm. The composite powder had a multiphase microstructure including nanocrystalline α-Fe/amorphous alloy core and amorphous carbon shell, and exhibited typical soft magnetic properties and a Mₛ of 145.3 emu/g. The composite powder/paraffin composite coating sample with a thickness of 2.5 mm exhibited great electromagnetic wave absorbing ability within a frequency of 4.0-6.0 GHz, a RLₘᵢₙ of −29.0 dB, and an optimal reflection loss peak at a frequency of 4.9 GHz, which could be used as a low-frequency wave absorber.

### EXAMPLE 5

### Fe-Based Nanocrystalline Alloy of Fe₈₀Si₁₀B₁₀ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₈₀Si₁₀B₁₀, and the ball milling was performed for 50 h; in step 3, the Fe-based nanocrystalline alloy powder and the carbon powder were mixed in a weight ratio of 95:5, and the ball milling was performed for 8 h.

The composite powder had an irregular spherical morphology. The composite powder had a multiphase microstructure including nanocrystalline α-Fe/amorphous alloy core and amorphous carbon shell, and exhibited typical soft magnetic properties, and a Mₛ of 167.8 emu/g. The composite powder/paraffin composite coating sample with a thickness of 1.9 mm exhibited a RLₘᵢₙ of −39.4 dB at a frequency of 6.4 GHz, and a Δf_{RL<-10 dB} of 4.1 GHz, which could have a better application prospect in the low frequency range. When the thickness of the composite coating sample was 1.3 mm, the Δf_{RL<-10 dB} reached 7.5 GHz.

### EXAMPLE 6

### Fe-Based Nanocrystalline Alloy of Fe₇₅Si₁₂B₁₃ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₇₅Si₁₂B₁₃; in step 3, the ball milling was performed for 8 h.

The composite powder also had a multiphase microstructure including nanocrystalline α-Fe/amorphous alloy core and amorphous carbon shell. The composite powder exhibited typical soft magnetic properties, and a Mₛ of 143.9 emu/g. The composite powder was irregularly spherical shaped. The composite powder/paraffin composite coating sample with a thickness of 2.0 mm exhibited a RLₘᵢₙ of −39.8 dB at a frequency of 6.0 GHz. When the thickness of the composite coating sample was 1.3 mm, the Δf_{RL<-10 dB} reached 7.6 GHz.

### EXAMPLE 7

### Fe-Based Nanocrystalline Alloy of Fe₇₀Si₁₅B₁₅ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₇₀Si₁₅B₁₅; in step 3, the Fe-based nanocrystalline alloy powder and the carbon powder were mixed in a weight ratio of 75:25, the mixing ball was performed for 8 h, and the ball-to-powder mass ratio was adjusted to 30:1.

The composite powder exhibited typical soft magnetic properties, and a Mₛ of 135.7 emu/g. The composite powder had an irregular spherical morphology. The composite powder/paraffin composite coating sample with a matching thickness of 2.2 mm exhibited a RLₘᵢₙ of −39.9 dB at a frequency of 5.1 GHz, and a Δf_{RL<-10 dB} of 3.1 GHz. When the thickness of the composite coating sample was 1.3 mm, the Δf_{RL<-10 dB} reached 6.6 GHz.

### EXAMPLE 8

### Fe-Based Nanocrystalline Alloy of Fe₆₇Ni₁₅Si₃B₁₅ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₆₇Ni₁₅Si₃B₁₅, and the ball milling was performed for 50 h; in step 3, the Fe-based nanocrystalline alloy powder and the carbon powder were mixed in a weight ratio of 95:5, and the ball milling was performed for 6 h.

The composite powder had a multiphase microstructure including nanocrystalline α-Fe/amorphous alloy core and amorphous carbon shell. The composite powder exhibited typical soft magnetic properties, and a Mₛ of 157.8 emu/g. The composite powder had irregularly spherical morphology. The composite powder/paraffin composite coating sample with a thickness of 2.1 mm exhibited a RLₘᵢₙ of −25.7 dB at a frequency of 10.8 GHz, and a Δf_{RL<-10 dB} of 3.0 GHz. When the thickness of the composite coating sample was 1.1 mm, the Δf_{RL<-10 dB} reached 5.9 GHz.

### EXAMPLE 9

### Fe-Based Nanocrystalline Alloy of Fe₇₆Co₄Ni₂Si₃B₁₅ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₇₆Co₄Ni₂Si₃B₁₅, and the ball milling was performed for 50 h; in step 3, the ball milling was performed for 6 h.

The composite powder had a multiphase microstructure including nanocrystalline α-Fe/amorphous alloy core and amorphous carbon shell. The composite powder exhibited typical soft magnetic properties, and a Mₛ of 155.7 emu/g. The composite powder had spherical-like morphology. The composite powder/paraffin composite coating sample with a thickness of 1.5 mm exhibited a RLₘᵢₙ of −32.1 dB at a frequency of 11.2 GHz, and a Δf_{RL<-10 dB} of 3.5 GHz.

### EXAMPLE 10

### Fe-Based Nanocrystalline Alloy of Fe₇₁Co₄Ni₂Si₁₅B₃Nb₃C₂ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₇₁Co₄Ni₂Si₁₅B₃Nb₃C₂; in step 3, the ball milling was performed for 6 h.

The composite powder had a multiphase microstructure including nanocrystalline α-Fe/amorphous alloy core and amorphous carbon shell. The composite powder exhibited typical soft magnetic properties, and a Mₛ of 150.2 emu/g. The composite powder had a spherical-flaky-mixed morphology. The composite coating sample exhibited a RLₘᵢₙ of −36.2 dB, an fₘ of 12.3 GHz, a dₘ of 1.4 mm, and a Δf_{RL<-10 dB} of 3.1 GHz, with a reduced thickness, which was more suitable for the application of wave absorbing coatings.

### EXAMPLE 11

### Fe-Based Nanocrystalline Alloy of Fe₆₇Co₈Ni₂Si₈B₈C₄Cu₁Mo₂ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₆₇Co₈Ni₂Si₈B₈C₄Cu₁Mo₂; in step 3, the Fe-based nanocrystalline alloy powder and the carbon powder were mixed in a weight ratio of 85:15, and the ball milling was performed for 6 h.

The composite powder exhibited a Ms of 148.3 emu/g. The composite powder had a multiphase microstructure including nanocrystalline α-Fe/amorphous alloy core and amorphous carbon shell. The composite powder had an irregular spherical morphology. The composite powder possessed a smaller matching thickness, which indicated its better wave absorbing performance. The composite coating sample with a matching thickness of only 1.2 mm exhibited a minimum RL of −20.2 dB at a frequency of 11.9 GHz, and a Δf_{RL<-10 dB} of 2.5 GHz.

### EXAMPLE 12

### Fe-Based Nanocrystalline Alloy of Fe₅₂Co₁₅Ni₂Si₁₅B₃C₈Cu₂Cr₁Mn₂ as the Core of the Composite Powder

The method for preparing the core-shell structured composite powder electromagnetic wave absorber formed by coating Fe-based nanocrystalline alloy with carbon was as follows:

Steps 1 to 4 were the same as described in Example 1, except that: in step 1, the composition of the Fe-based nanocrystalline alloy was adjusted to Fe₅₂Co₁₅Ni₂Si₁₅B₃C₈Cu₂Cr₁Mn₂; in step 3, the Fe-based nanocrystalline alloy powder and the carbon powder were mixed in a weight ratio of 75:25, and the ball milling was performed for 6 h.

The composite powder had an irregular spherical morphology. The composite powder had a multiphase microstructure including nanocrystalline α-Fe/amorphous alloy core and amorphous carbon shell. The composite powder exhibited typical soft magnetic properties, and a Mₛ of 135.8 emu/g. The composite powder/paraffin composite coating sample with a thickness of 1.0 mm, exhibited a RLₘᵢₙ of −15.3 dB at a frequency of 15.7 GHz, and a Δf_{RL<-10 dB} of 3.3 GHz.

### Comparative Example 1

Fe₉₀Si₇B₃ was used as the wave absorber.

The method for preparing the wave absorber was as follows:

Step 1: Preparing a Fe-Based Nanocrystalline Alloy Powder

a. raw materials of Fe, Si, and B (each with a purity of not less than 99 wt %) were weighed according to the nominal composition of Fe₉₀Si₇B₃, and mixed;

b. the resulting mixed material was smelted repeatedly for four times in a non-consumable-electrode arc furnace in an argon atmosphere, obtaining a chemically uniform master alloy ingot;

c. the master alloy ingot was mechanically crushed and screened, obtaining an alloy powder with a particle size of less than 300 μm;

d. the alloy powder was placed in a stainless steel ball milling tank in a ball-to-powder mass ratio of 20:1. The stainless steel ball milling tank was then vacuumized, charged with argon gas as a protective gas, and sealed. The sealed stainless steel ball milling tank was placed in a planetary ball mill for ball milling. The ball milling was performed for 85 h, at a rotation speed of 350 rpm, with a shut down of 5 minutes for every 30 minutes of milling to cool, in a forward and reverse operation mode to ensure a uniform ball milling. After a cooling of 0.5 h, a product was taken out, obtaining a Fe-based nanocrystalline alloy powder with a particle size of 2.8 μm.

Step 2: Structure Characterization, Morphology Observation and Performance Test of the Fe-Based Nanocrystalline Alloy Powder

This step was the same as the step 4 in Example 1.

The Fe-based nanocrystalline alloy powder had a spherical-like morphology, a nanocrystalline α-Fe/amorphous dual-phase structure. The Fe-based nanocrystalline alloy powder exhibited typical soft magnetic properties, and a Ms of 196.3 emu/g. The alloy powder/paraffin composite sample with a thickness of 2.4 mm exhibited a RLₘᵢₙ of −16.7 dB, a Δf_{RL<-10 dB} of 5.2 GHz, and an optimal reflection loss peak at a frequency of 13.8 GHz. Compared with Comparative Example 1, the composite coating samples of examples of the present disclosure has a smaller thickness, a lower RL, and a larger Δf_{RL<-10 dB}, indicating a greater electromagnetic wave absorbing ability.

### Comparative Example 2

Comparative Example 2 was performed according to CHUAI. The composite sample prepared from the electromagnetic wave absorber (with a thickness of 2.0 mm) exhibited a RLₘᵢₙ of −45.3 dB, but a Δf_{RL<-10 dB} of only 5.4 GHz. Furthermore, the electromagnetic wave absorber had a complicated and higher-cost preparation process. That is to say, the gas atomization method combined with a wet ball milling had a longer period, and was more difficult to control. Compared with Comparative Example 2, the wave absorbers of examples of the present disclosure has the advantages of a simpler preparation process, a larger Δf_{RL<-10 dB}, and a smaller sample thickness.

### Comparative Example 3

Comparative Example 3 was performed according to the reference DUAN et al., Graphene to Tune Microwave Absorption Frequencies and Enhance Absorption Properties of Carbonyl Iron/Polyurethane Coating, Progress in Organic Coatings, Vol. 125 (2018) pages 89-98 “DUAN”. DUAN prepared a carbonyl iron/graphene/polyurethane composite wave absorbing coating by a ultrasonic mixing-rolling-curing method. When the coating had a thickness of 1 mm, the wave absorbing coating exhibited a RLₘᵢₙ of −27.0 dB, and a Δf_{RL<-10 dB} of 6.5 GHz. In contrast, the method for preparing the electromagnetic wave absorber according to the present disclosure is simple and effective, allows for controllable ball milling process conditions, and thus is suitable for industrial production. In terms of performance, the electromagnetic wave absorber coating according to the present disclosure exhibited greater wave absorbing ability, and a RLₘᵢₙ of −54.7 dB, and allowed for a Δf_{RL<-10 dB} of 7.3 GHz when the thickness was 1.7 mm Compared with Comparative Example 3, the electromagnetic wave absorbers of examples of the present disclosure had the advantages of a simpler preparation process, greater wave absorbing ability, and larger Δf_{RL<-10 dB}.

### Comparative Example 4

Comparative Example 4 was performed according to the reference XIONG et al., Carbon Coated Core-Shell FeSiCr/Fe3C Embedded in Carbon Nanosheets Network Nanocomposites for Improving Microwave Absorption Performance, Nano, Vol. 15 (2020) 2050094 “XIONG”. XIONG synthesized FeSiCr/Fe₃C@C/C nanocomposite powder by an arc melting method combined with an arc discharge plasma. The composite sample prepared from the wave absorber with a thickness of 2.4 mm exhibited a RLₘᵢₙ of −42.3 dB, and a Δf_{RL<-10 dB} of only 3.7 GHz. In contrast, the wave absorber prepared in the present disclosure exhibited better wave absorbing performance. The composite coating sample prepared from the wave absorber exhibited a RLₘᵢₙ of −54.7 dB, and a Δf_{RL<-10 dB} of 6.5 GHz when the thickness of the composite coating sample was 1.9 mm, which met the comprehensive performance requirements “thinner, lighter, and broader and greater”. In terms of the process preparation, the method according to the present disclosure is effective, reliable and convenient. Compared with Comparative Example 4, the wave absorber of examples of the present disclosure has the advantages of a simpler preparation process and more excellent wave absorbing performance.

Detailed data of Examples 1-12 and Comparative Examples 1-4 are shown in Table 1 and Table 2.

TABLE 1
Composition of the core alloy, content of the shell carbon layer, time for ball milling
and electromagnetic wave absorbing performance of the composite powder of Examples 1-12

| | Composition | Content of | Time for ball- | | | | | |
|---|---|---|---|---|---|---|---|---|
| | of the core alloy | carbon | milling | | | | | |
| | (atom %) | (wt %) | a + b/h | Mₛ/emu/g | RLₘᵢₙ/dB | fₘ/GHz | Δf_{RL<-10 dB}/GHz | dₘ/mm |
| Example 1 | Fe₉₀Si₇B₃ | 8 | 85 + 10 | 157.6 | −54.8 | 12.7 | 6.5 | 1.9 |
| Example 2 | Fe₉₀Si₇B₃ | 15 | 85 + 10 | 145.7 | −23.2 | 17.5 | 4.2 | 1.6 |
| Example 3 | Fe₈₇Si₃B₁₀ | 5 | 70 + 10 | 163.4 | −17.5 | 13.0 | 5.1 | 2.3 |
| Example 4 | Fe₈₂Si₁₅B₃ | 25 | 50 + 10 | 145.3 | −29.0 | 4.9 | 2.0 | 2.5 |
| Example 5 | Fe₈₀Si₁₀B₁₀ | 5 | 50 + 8 | 167.8 | −39.4 | 6.4 | 4.1 | 1.9 |
| Example 6 | Fe₇₅Si₁₂B₁₃ | 8 | 85 + 8 | 143.9 | −39.8 | 6.0 | 3.6 | 2.0 |
| Example 7 | Fe₇₀Si₁₅B₁₅ | 25 | 85 + 8 | 135.7 | −39.9 | 5.1 | 3.1 | 2.2 |
| Example 8 | Fe₆₇Ni₁₅Si₃B₁₅ | 5 | 50 + 6 | 157.8 | −25.7 | 10.8 | 3.0 | 2.1 |
| Example 9 | Fe₇₆Co₄Ni₂Si₃B₁₅ | 8 | 50 + 6 | 155.7 | −32.1 | 11.2 | 3.5 | 1.5 |
| Example 10 | Fe₇₁Co₄Ni₂Si₁₅B₃Nb₃C₂ | 8 | 85 + 6 | 150.2 | −36.2 | 12.3 | 3.1 | 1.4 |
| Example 11 | Fe₆₇Co₈Ni₂Si₈B₈C₄Cu₁Mo₂ | 15 | 85 + 6 | 148.3 | −20.2 | 11.9 | 2.5 | 1.2 |
| Example 12 | Fe₅₂Co₁₅Ni₂Si₁₅B₃C₈Cu₂Cr₁Mn₂ | 25 | 85 + 6 | 135.8 | −15.3 | 15.7 | 3.3 | 1.0 |

In Table 1, time for ball milling a+b: a represents time for ball milling during the preparation of the alloy powder, and b represents time for ball milling after mixing; Mₛ represents saturation magnetization; RLₘᵢₙ represents the minimum reflection loss; fₘ represents optimum matching frequency; Δf_{RL<-10 dB} represents effective absorption bandwidth; and dₘ represents optimum matching thickness.

TABLE 2
Electromagnetic wave absorbing performance of the composite sample prepared from the powder of Comparative Examples 1 to 4

| | Composition | | | | | | |
|---|---|---|---|---|---|---|---|
| | of the absorber | | | | | | Preparation |
| Items | (atom %) | Mₛ/emu/g | RLₘᵢₙ/dB | fₘ/GHz | Δf_{RL<-10 dB}/GHz | dₘ/mm | process |
| Comparative | Fe₉₀Si₇B₃ | 196.3 | −16. 7 | 13.8 | 5.2 | 2.4 | Ball milling |
| Example 1 | | | | | | | |
| Comparative | Fe_{0.2}P_{0.05}C_{0.45}B_{0.3}/graphene | 148.1 | −45.3 | 12.6 | 5.4 | 2.0 | Gas atomization combined |
| Example 2 | | | | | | | with ball milling |
| Comparative | CIP/graphene/polyurethane | — | −27.0 | 12.9 | 6.5 | 1.0 | Ultrasonic mixing, |
| Example 3 | | | | | | | rolling, and curing |
| Comparative | Fe_{83.36}Si_{14.55}Cr_{2.09}/Fe₃C@C | 123.7 | −42.3 | 11.5 | 3.7 | 2.4 | Plasma arc method |
| Example 4 | | | | | | | |

In Table 2, Mₛ represents saturation magnetization; RLₘᵢₙ represents minimum reflection loss; fₘ represents optimum matching frequency; Δf_{RL<-10 dB} represents effective absorption bandwidth; and dₘ represents optimum matching thickness.

Finally, it should be noted that the above embodiments are only used to illustrate the technical solutions of the present disclosure, not to limit them. Although the technical solutions of present disclosure has been described in detail with reference to the foregoing embodiments, those of ordinary skill in the art should understand that the technical solutions recited in the foregoing embodiments could still be modified, or some or all of the technical features could be replaced with equivalents; these modifications or replacements shall not render the corresponding technical solutions out of the scope of technical solutions of the present disclosure.

What is claimed is:

1. A core-shell structured composite powder electromagnetic wave absorber formed by coating Fe-based nanocrystalline alloy with carbon, comprising a core of an Fe-based nanocrystalline alloy, and a shell of an amorphous carbon layer, the shell accounting for 5-25 wt % of the core-shell structured composite powder electromagnetic wave absorber, wherein
the core-shell structured composite powder electromagnetic wave absorber has a spherical-like core-shell structure, and a particle size of 3-10 μm;
the Fe-based nanocrystalline alloy has a composition formula of Fe_{bal.}SiₐB_{b},
where a and b represent an atomic percentage content of a corresponding element respectively, and meet requirements of
3≤a≤15,
3≤b≤15, and
a balance being an atomic percentage content of Fe;
the Fe-based nanocrystalline alloy has an amorphous/α-Fe dual-phase structure, wherein the α-Fe has a grain size of 10-30 nm; and
the amorphous carbon layer has an average thickness of 0.3-1 μm.

2. The core-shell structured composite powder electromagnetic wave absorber as claimed in claim 1, wherein the Fe-based nanocrystalline alloy has a composition formula of Fe_{bal.}CoₓNi_{y}SiₐB_{b}C_{c}Cu_{d}TMₑ,
where TM represents at least one selected from the group consisting of Nb, Mo, Cr, and Mn;
where x, y, a, b, c, d, and e represent an atomic percentage content of a corresponding element respectively, and meet requirements of
0≤x≤15,
0≤y≤15,
0≤x+y≤20,
0≤a≤15,
0≤b≤15,
0≤c≤15,
b 6≤a+b+c≤30,
0≤d≤2,
0≤e≤4, and
a balance being an atomic percentage content of Fe.

3. The core-shell structured composite powder electromagnetic wave absorber as claimed in claim 1, wherein an electromagnetic wave absorber coating is formed from a mixture of the core-shell structured composite powder electromagnetic wave absorber and a wave-transparent matrix in a mass ratio of 3:2, and under a condition that the electromagnetic wave absorber coating has a thickness of 1.5-2.5 mm, the electromagnetic wave absorber coating exhibits a reflection loss lower than −10 dB within a frequency of 8-18 GHz, and a minimum reflection loss of −54 dB.

4. The core-shell structured composite powder electromagnetic wave absorber as claimed in claim 2, wherein an electromagnetic wave absorber coating is formed from a mixture of the core-shell structured composite powder electromagnetic wave absorber and a wave-transparent matrix in a mass ratio of 3:2, and under a condition that the electromagnetic wave absorber coating has a thickness of 1.5-2.5 mm, the electromagnetic wave absorber coating exhibits a reflection loss lower than −10 dB within a frequency of 8-18 GHz, and a minimum reflection loss of −54 dB.

5. A method for preparing the core-shell structured composite powder electromagnetic wave absorber formed by coating Fe-based nanocrystalline alloy with carbon as claimed in claim 1, comprising
i) preparing a Fe-based nanocrystalline alloy powder by
a) providing raw materials according to a nominal composition formula of the Fe-based nanocrystalline alloy, each of the raw materials having a purity of not less than 99 wt %;
b) mixing the raw materials, and melting a resulting mixed material in an induction melting furnace or a non-consumable-electrode arc furnace in an argon atmosphere, to obtain a chemically uniform master alloy ingot;
c) crushing the master alloy ingot and screening, to obtain an alloy powder with a particle size of less than 300 μm; and
d) placing the alloy powder in a stainless steel ball mill tank in a ball-to-powder mass ratio of 20:1; vacuumizing the stainless steel ball mill tank and charging with argon gas, sealing the stainless steel ball mill tank and placing a sealed stainless steel ball mill tank in a planetary ball mill, and ball milling for 50-85 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the Fe-based nanocrystalline alloy powder with a particle size of 2-8 μm;
ii) using a commercial carbon powder or preparing a carbon powder by steps of
a) mechanically crushing graphite and screening, to obtain a graphite powder with a particle size of less than 300 μm; and
b) placing the graphite powder in a stainless steel ball mill tank in a ball-to-powder mass ratio of 20:1, vacuumizing the stainless steel ball mill tank and charging with argon gas, sealing the stainless steel ball mill tank and placing a sealed stainless steel ball mill tank in a planetary ball mill, and ball milling for 30 h, at a rotation speed of 350 rpm, with a shut down of 5 minutes for every 30 minutes of milling to cool, in a forward and reverse operation mode to ensure a uniform ball milling; cooling for 0.5 h and taking out, to obtain the carbon powder with a particle size of 1-3 μm; and
iii) preparing a core-shell structured composite powder electromagnetic wave absorber by
a) mixing the Fe-based nanocrystalline alloy powder obtained in step 1 and the carbon powder obtained in step 2 in a preset ratio, and placing a resulting mixture in a stainless steel ball milling tank in a ball-to-powder mass ratio of 20:1 or 30:1, vacuumizing the stainless steel ball mill tank and charging with argon gas, sealing the stainless steel ball mill tank and placing a sealed stainless steel ball mill tank in a planetary ball mill, and ball milling for 6-10 h, at a rotation speed of 200 rpm, with a shut down of 5 minutes for every 30 minutes of milling to cool, in a forward and reverse operation mode to ensure a uniform ball milling; cooling for 0.5 h and taking out, to obtain the core-shell structured composite powder electromagnetic wave absorber with a particle size of 3-10 μm.

6. The method as claimed in claim 5, wherein the Fe-based nanocrystalline alloy has a composition formula of Fe_{bal.}CoₓNi_{y}SiₐB_{b}C_{c}Cu_{d}TMₑ,
where TM represents at least one selected from the group consisting of Nb, Mo, Cr, and Mn; x, y, a, b, c, d, and e represent an atomic percentage content of a corresponding element respectively, and meet requirements of
0≤x≤15,
0≤y≤15,
0≤x+y≤20,
0≤a≤15,
0≤b≤15,
0≤c≤15,
6≤a+b+c≤30,
0≤d≤2,
0≤e≤4, and
a balance being an atomic percentage content of Fe.
